(19) United States
(12) Patent Application Publication
(10) Pub. No.: US 2026/0123200 A1
(43) Pub. Date: Apr. 30, 2026

(54) DISPLAY SUBSTRATE AND DISPLAY PANEL

(71) Applicant: HKC CORPORATION LIMITED, Shenzhen (CN)

(72) Inventors: CHEN WANG, Shenzhen (CN); Chengshun Zhu, Shenzhen (CN); Hejun Ning, Shenzhen (CN); Meng Wang, Shenzhen (CN); Xueyong Huang, Shenzhen (CN); Shulin Yuan, Shenzhen (CN); Lidan Ye, Shenzhen (CN)

(21) Appl. No.: 19/365,048

(22) Filed: Oct. 21, 2025

(30) Foreign Application Priority Data
Oct. 31, 2024 (CN) 202411549407.X

(51) Int. Cl. H10K 59/124; G02F 1/1368; H10D 86/60; H10K 59/12; H10K 59/122

(52) U.S. Cl. CPC H10K 59/124; G02F 1/1368; H10D 86/60; H10K 59/1201; H10K 59/122

(57) ABSTRACT

A display substrate and a display panel are disclosed. The display substrate includes a base, a first insulating layer, a semiconductor layer, a second insulating layer, a metal layer, and a third insulating layer that are sequentially stacked. The semiconductor layer and the metal layer form part of a thin film transistor in the display substrate. The display substrate further includes at least one channel, which is located on at least one side of the thin film transistor and penetrates through the first insulating layer and the second insulating layer. The third insulating layer fills the channel and is bonded to the base within the at least one channel.

### CROSS-REFERENCE TO RELATED APPLICATIONS

The present application claims the priority and benefit of Chinese patent application number 202411549407X, titled “Display Substrate and Display Panel” and filed Oct. 31, 2024 with China National Intellectual Property Administration, the entire contents of which are incorporated herein by reference.

### TECHNICAL FIELD

The present application relates to the field of display technology, and more particularly relates to a display substrate and a display panel.

### BACKGROUND

The description provided in this section is intended for the mere purpose of providing background information related to the present application but does not necessarily constitute prior art.

Thin film transistor (TFT), as a key semiconductor device, has been widely applied in modern electronic technologies. Especially in flat panel display technologies such as liquid crystal displays (LCDs) and organic light-emitting diode displays (OLEDs), with the development of various new display technologies, the performance requirements for thin film transistors have been increasing, particularly in terms of stability. Through the development of new materials, design optimization, manufacturing process improvements, and encapsulation technology enhancements, future thin film transistors will better meet increasingly stringent application requirements, thereby expanding their application scope and depth in the global electronics market.

The metal layer and semiconductor layer in thin film transistors may be susceptible to intrusion by external moisture or free ions, causing degradation of the TFT device characteristics. Therefore, preventing the metal layer and the semiconductor layer in thin film transistors from intrusion by external moisture or free ions is an important research direction in the display field.

### SUMMARY

It is therefore one purpose of embodiments of the present application to provide a display substrate and a display panel that prevent the metal layer and the semiconductor layer in the thin film transistor from intrusion by external moisture or free ions.

An embodiment of the present application discloses a display substrate. The display substrate includes a base, a first insulating layer, a semiconductor layer, a second insulating layer, a metal layer, and a third insulating layer. The first insulating layer is disposed on the base. The semiconductor layer is disposed on the side of the first insulating layer facing away from the base. The second insulating layer is disposed on the side of the semiconductor layer facing away from the first insulating layer. The metal layer is disposed on the side of the second insulating layer facing away from the semiconductor layer. The third insulating layer is disposed on the metal layer. The semiconductor layer and the metal layer form part of a thin film transistor in the display substrate. The display substrate further includes at least one channel. The at least one channel is located on at least one side of the thin film transistor and penetrates through the first insulating layer and the second insulating layer. The third insulating layer further fills the channel and adheres to the base within the channel.

In some embodiments, the display substrate further includes a first bank structure, the first bank structure being disposed between the second insulating layer and the third insulating layer, adjacent to the channel. The first bank structure is made of an insulating material. The binding strength between the first bank structure and the second insulating layer is greater than the binding strength between the first bank structure and the third insulating layer.

In some embodiments, the display substrate further includes a second bank structure, where the second bank structure is disposed between the second insulating layer and the third insulating layer, and the channel is disposed between the first bank structure and the second bank structure. The first bank structure and the second bank structure are formed by the same manufacturing procedure.

In some embodiments, the area of the first bank structure contacting the second insulating layer is greater than the area of the first bank structure contacting the third insulating layer. The area of the second bank structure contacting the second insulating layer is greater than the area of the second bank structure contacting the third insulating layer.

In some embodiments, in the thickness direction of the base, the cross-section of the first bank structure is trapezoidal. The width of the side of the first bank structure contacting the second insulating layer is 2.8 μm to 3.2 μm. The width of the side of the first bank structure contacting the third insulating layer is 1.5 μm to 2.5 μm. The height of the first bank structure is 0.5 μm to 0.8 μm.

In some embodiments, the material of the first bank structure is identical with the material of the second insulating layer and different from the material of the third insulating layer; and/or a deposition rate of the first bank structure during film formation is higher than that of the third insulating layer during film formation.

In some embodiments, the display substrate further includes a third bank structure. The third bank structure is located between the first insulating layer and the second insulating layer, arranged side by side horizontally with the semiconductor layer, and the third bank structure is also disposed between the semiconductor layer and the channel. The third bank structure is made of an insulating material. The binding strength between the third bank structure and the first insulating layer is greater than the binding strength between the third bank structure and the second insulating layer.

In some embodiments, in the thickness direction of the base, the cross section of the channel is an inverted trapezoid. The bottom width of the channel is 0.5 μm to 1 μm. The top width of the channel is 1 μm to 2 μm. The height of the channel is 0.5 μm to 1.5 μm.

In some embodiments, the display substrate includes a plurality of channels, which are arranged in the display area of the display substrate and disposed in one-to-one correspondence with the thin film transistors. Each of the channels is arranged to surround the corresponding thin film transistor. Alternatively, the plurality of channels are arranged in the non-display area of the display substrate, surrounding the display area of the display substrate. Alternatively, the plurality of channels are arranged on both sides of the display substrate and arranged along the length direction of the metal layer.

An embodiment of the present application further discloses a display panel, where the display panel includes the above-mentioned display substrate.

The advantageous effects of the embodiments of the present application are as follows. Due to external moisture or free ions penetrating from the bonding interfaces between layers in the display substrate, the metal layer and semiconductor layer in the thin film transistor may be invaded by harmful substances such as the moisture or free ions, thereby affecting the device characteristics of the thin film transistor. Embodiments of the present application add a channel penetrating through the first insulating layer and the second insulating layer in the display substrate, and fills the channel with the third insulating layer. Therefore, no matter whether harmful substances such as external moisture or free ions invade through the bonding interface between the third insulating layer and the second insulating layer, or through the bonding interface between the second insulating layer and the first insulating layer, since these harmful substances cannot penetrate the layers themselves, they can only invade along the surface of the third insulating layer within the channel toward the metal layer and the semiconductor layer, which lengthens the invasion path of the harmful substances, thereby slowing down or even blocking the invasion and penetration of moisture or free ions into the metal layer and the semiconductor layer in the thin film transistor, thus ensuring the device characteristics of the thin film transistor.

### BRIEF DESCRIPTION OF DRAWINGS

The accompanying drawings are used to provide a further understanding of the embodiments according to the present application, and constitute a part of the specification. They are used to illustrate the embodiments according to the present application, and explain the principles of the present application in conjunction with the text description. Apparently, the drawings in the following description merely represent some embodiments of the present disclosure, and for those having ordinary skill in the art, other drawings may also be obtained based on these drawings without investing creative. In the drawings:

FIG. 1 is a schematic diagram of a display panel provided by an embodiment of the present application.

FIG. 2 is a schematic diagram of a display substrate provided by an embodiment of the present application.

FIG. 3 is a schematic diagram of a display substrate provided by an implementation in an embodiment of the present application.

FIG. 4 is a schematic diagram of a display substrate provided by another implementation in the embodiment of the present application.

FIG. 5 is a schematic diagram of a display substrate provided by yet another implementation in the embodiment of the present application.

FIG. 6 is a schematic diagram of a display substrate provided by still another implementation in the embodiment of the present application.

FIG. 7 is a schematic diagram of a display substrate based on the design of a channel provided by an embodiment of the present application.

FIG. 8 is a schematic diagram of a display substrate based on the design of a second insulating layer provided by an embodiment of the present application.

FIG. 9 is a process flowchart of a display substrate provided by an embodiment of the present application.

In the drawings: 10, display panel; 20, display substrate; 100, thin film transistor; 110, base; 120, gate electrode; 130, first insulating layer; 140, semiconductor layer; 150, second insulating layer; 151, first insulating dielectric layer; 152, second insulating dielectric layer; 160, metal layer; 170, third insulating layer; 180, organic insulating layer; 190, pixel defining layer; 200, first bank structure; 300, second bank structure; 400, third bank structure; 500, fourth bank structure; 600, channel.

### DETAILED DESCRIPTION OF EMBODIMENTS

It should be understood that the terms used herein, the specific structures and functional details disclosed therein are merely representative for describing some specific embodiments, but the present application can be implemented in many alternative forms and should not be construed as being limited to only these embodiments described herein.

In addition, unless otherwise clearly specified and defined, terms “connected to”, “coupled to”, etc., should be understood in a broad sense. For example, it may be a fixed connection, a detachable connection, or an integral connection; it may be a mechanical connection or an electrical connection; it may be a direct connection or an indirect connection through an intermediate medium, or it may be internal communication between two elements. For those of ordinary skill in the art, the specific meanings of the above terms as used in the present application can be understood depending on specific contexts.

As used herein, unless otherwise specified or defined, when referring to a “trapezoid,” it refers to an upright trapezoid, in which the lower base is relatively longer and the upper base is relatively shorter, thereby forming an upright trapezoidal shape, whereas when referring to an “inverted trapezoid,” it means that the lower base is relatively shorter and the upper base is relatively longer, thereby forming an inverted trapezoidal shape.

As used herein, the term “horizontally” or “horizontal” refers to a positional relationship in which two or more features are located or disposed at substantially the same height or vertical level, such that they are aligned or arranged side by side in a direction parallel to the horizontal plane. In some embodiments, this may indicate that the features are formed in or on the same layer of a multilayer structure, such as a display panel. This terminology is used to describe the relative arrangement of structural elements and does not necessarily imply a specific manufacturing sequence or absolute physical position in space. Furthermore, all positional and directional references, including “horizontally,” are to be understood as relative descriptions based on the orientation shown in the accompanying drawings. That is, when a reader views the drawings in the standard upright orientation, the features described as being horizontally arranged appear to be situated on the same level with respect to the viewing direction. Such descriptions are intended solely for ease of understanding and do not limit the scope of the present application to any particular orientation during use or fabrication.

The present application will be described in further detail below with reference to the accompanying drawings and some optional embodiments.

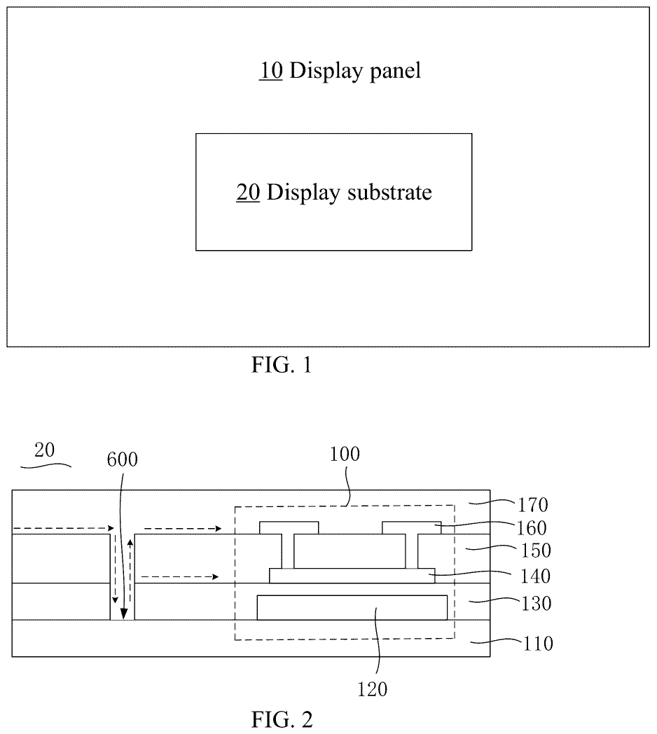

As shown in FIG. 1, embodiments of the present application provide a display panel. The display panel 10 may be a liquid crystal display panel (LCD), an organic light-emitting diode display panel (OLED), or other types of display panels. When the display panel 10 is a liquid crystal display panel, the liquid crystal display panel includes an array substrate and a color filter substrate that are oppositely arranged, and a liquid crystal layer disposed between the array substrate and the color filter substrate. At this time, the display substrate 20 is the array substrate. The display substrate 20 includes a plurality of pixel elements that are arranged in an array. Each pixel element is connected to a corresponding thin film transistor. A drain electrode of the thin film transistor is connected to a pixel electrode of the pixel element, thus powering the pixel electrode of this pixel element via the thin film transistor. In some liquid crystal display panels, the display substrate 20 is further integrated with a gate driving circuit (also referred to as Gate on Array or GOA for short). The GOA circuit further includes multiple thin film transistors, where the thin film transistors act as switches to control the transmission of scan signals. As shown in FIG. 2, when the display panel 10 (as shown in FIG. 1) is an organic light-emitting diode display panel, the display substrate 20 includes pixel elements arranged in an array and a cover plate disposed on the pixel elements. Each pixel element corresponds to multiple thin film transistors, which control the activation of this pixel element.

Embodiments of the present application further provide a display substrate 20, which can be used in a liquid crystal display panel, an organic light-emitting diode display panel, or other types of display panels.

As shown in FIG. 2, the display substrate 20 includes a base 110, a first insulating layer 130, a semiconductor layer 140, a second insulating layer 150, a metal layer 160, and a third insulating layer 170. The first insulating layer 130 is disposed on the base 110. The semiconductor layer 140 is disposed on the side of the first insulating layer 130 facing away from the base 110. The second insulating layer 150 is disposed on the side of the semiconductor layer 140 facing away from the first insulating layer 130. The metal layer 160 is disposed on the side of the second insulating layer 150 facing away from the semiconductor layer 140. The third insulating layer 170 is disposed on the metal layer 160. The semiconductor layer 140 and the metal layer 160 form part of each thin film transistor 100 in the display substrate 20. The display substrate 20 further includes at least one channel 600, disposed on at least one side of the thin film transistor, where the at least one channel 600 penetrates through the first insulating layer 130 and the second insulating layer 150. The third insulating layer 170 further fills the at least one channel 600 and is bonded to the base 110 within the at least one channel 600.

The metal layer 160 includes a source electrode and a drain electrode. The semiconductor layer 140 may be made of a metal-oxide semiconductor, polycrystalline silicon, or other types of semiconductor materials. The source electrode and the drain electrode are each connected to the semiconductor layer 140 through a via. The thin film transistor 100 further includes a gate electrode 120. The thin film transistor 100 may be a top gate structure or a bottom gate structure. When the thin film transistor 100 is a bottom gate structure, the gate electrode 120 is disposed between the base 110 and the first insulating layer 130. When the thin film transistor 100 is a top gate structure, the gate electrode 120 is disposed above the semiconductor layer 140.

Due to external moisture or free ions penetrating from the bonding interfaces between layers in the display substrate 20, the metal layer 160 and semiconductor layer 140 in the thin film transistor 100 may be invaded by harmful substances such as the moisture or free ions, thereby affecting the device characteristics of the thin film transistor 100. Embodiments of the present application add a channel 600 penetrating through the first insulating layer 130 and the second insulating layer 150 in the display substrate 20, and fills the channel 600 with the third insulating layer 170. Therefore, no matter whether harmful substances such as external moisture or free ions invade through the bonding interface between the third insulating layer 170 and the second insulating layer 150, or through the bonding interface between the second insulating layer 150 and the first insulating layer 130, since these harmful substances cannot penetrate the layers themselves, they can only invade along the surface of the third insulating layer 170 within the channel 600 toward the metal layer 160 and the semiconductor layer 140, which lengthens the invasion path of the harmful substances, thereby slowing down or even blocking the invasion and penetration of moisture or free ions into the metal layer 160 and the semiconductor layer 140 in the thin film transistor 100, thus ensuring the device characteristics of the thin film transistor 100.

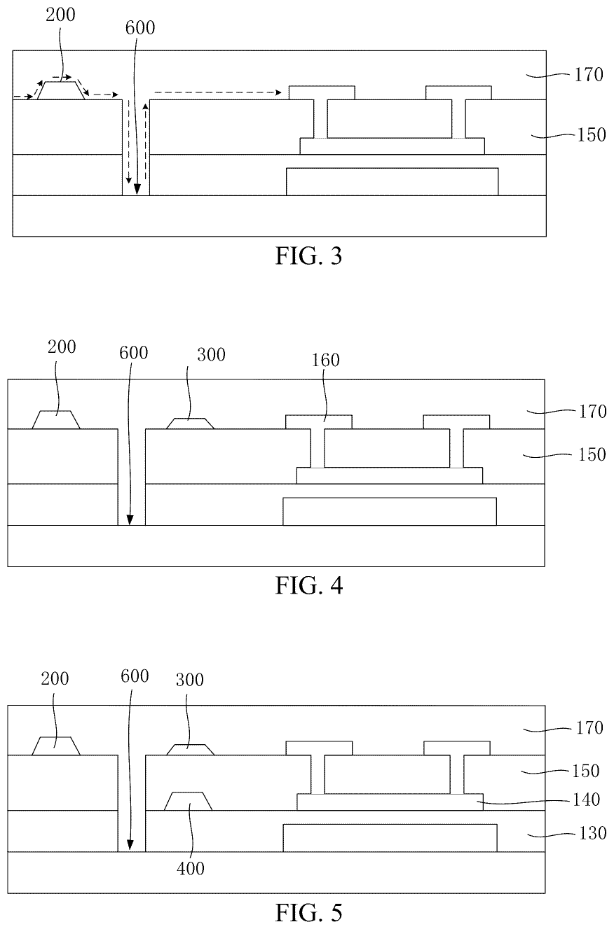

As one implementation, as shown in FIG. 3, the display substrate 20 further includes a first bank structure 200. The first bank structure 200 is disposed between the second insulating layer 150 and the third insulating layer 170, adjacent to the channel 600, and disposed on the side of the channel 600 facing away from the metal layer 160, i.e., on an outside of the channel 600. The first bank structure 200 may be made of an insulating material. The binding strength between the first bank structure 200 and the second insulating layer 150 is greater than that between the first bank structure 200 and the third insulating layer 170.

The arrow direction in FIG. 3 indicates the invasion path of harmful substances such as moisture or free ions from the bonding interface between the third insulating layer 170 and the second insulating layer 150 toward the metal layer 160. As shown in the figure, due to the presence of the first bank structure 200 and the relatively large binding strength between the first bank structure 200 and the second insulating layer 150, harmful substances invading from the bonding interface between the third insulating layer 170 and the second insulating layer 150 toward the metal layer 160 can only invade along the sides and top of the first bank structure 200, and cannot invade through the bonding interface between the first bank structure 200 and the second insulating layer 150, thereby extending the invasion path of the harmful substances. This implementation, by combining the designs of the first bank structure 200 and the channel 600, greatly slows down or even blocks the invasion and penetration of harmful substances such as moisture or free ions into the source electrode and the drain electrode in the thin film transistor 100 (as illustrated in FIG. 2).

In this implementation, the material of the first bank structure 200 is identical with that of the second insulating layer 150, and different from that of the third insulating layer 170. For example, the materials of the first bank structure 200 and the second insulating layer 150 are both silicon oxide, while the material of the third insulating layer 170 is silicon nitride or aluminum oxide. Through the above design, due to better mutual adhesion between the identical materials, the binding strength between the first bank structure 200 and the second insulating layer 150 can be greater than that between the first bank structure 200 and the third insulating layer 170.

Alternatively, in this implementation, the film formation rate of the first bank structure 200 may be higher than that of the third insulating layer 170. Since the slower the film formation rate during fabrication, the higher the film density and the better the contact effect with the underlying film layer, through the above design, the binding strength between the first bank structure 200 and the second insulating layer 150 can be higher than that between the first bank structure 200 and the third insulating layer 170.

Of course, in this embodiment, the material of the first bank structure 200 can be the identical with that of the second insulating layer 150 and different from that of the third insulating layer 170; furthermore, the film formation rate of the first bank structure 200 can be higher than that of the third insulating layer 170, so as to further increase the binding strength between the first bank structure 200 and the second insulating layer 150.

In this implementation, the area of the first bank structure 200 in contact with the second insulating layer 150 is greater than the area of the first bank structure 200 in contact with the third insulating layer 170. On the one hand, this facilitates manufacturing process design; on the other hand, the uphill and downhill terrain on the sides of the first bank structure 200 guides harmful substances such as moisture or free ions, preventing their accumulation at the bottom of the first bank structure 200, which could otherwise lead to excessive buildup of the harmful substances and break the binding strength between the first bank structure 200 and the second insulating layer 150.

In this embodiment, in the thickness direction of the base 110, the cross-section of the first bank structure 200 is trapezoidal. The width of the side of the first bank structure 200 in contact with the second insulating layer 150 is 2.8-3.2 μm. The width of the side of the first bank structure 200 in contact with the third insulating layer 170 is 1.5-2.5 μm. The height of the first bank structure 200 is 0.5-0.8 μm. Through the above design, after adding the first bank structure 200 inside the display substrate 20, the overall thickness of the display substrate 20 is not increased, while still ensuring the blocking effect of the first bank structure 200 against harmful substances such as moisture or free ions.

In other implementations, the first bank structure 200 may not be trapezoidal, but may be triangular or polygonal. Furthermore, the area of the first bank structure 200 in contact with the second insulating layer 150 may be less than or equal to the area of the first bank structure 200 in contact with the third insulating layer 170. The first bank structure 200, using these designs, can all block harmful substances such as moisture or free ions.

Of course, in other implementations, the first bank structure 200 may also be arranged between the metal layer 160 and the channel 600, disposed on the inner side of the channel 600.

As another implementation, as shown in FIG. 4, this implementation additionally provides a second bank structure 300 based on the implementation of FIG. 3. The second bank structure 300 is also disposed between the second insulating layer 150 and the third insulating layer 170, with the first bank structure 200 and the second bank structure 300 located on opposite sides of the channel 600, respectively. Furthermore, similar to the first bank structure 200, the binding strength between the second bank structure 300 and the second insulating layer 150 is greater than that between the second bank structure 300 and the third insulating layer 170.

This implementation further extends the invasion path of harmful substances such as moisture or free ions by adding the second bank structure 300, effectively protecting the source electrode and drain electrode structures.

In this implementation, the first bank structure 200 and the second bank structure 300 are formed by the same manufacturing procedure. Regarding the specific shape and process design of the second bank structure 300, refer to the description of the first bank structure 200 in the previous implementation and will not be repeated herein.

As another implementation, as shown in FIG. 5, the display substrate 20 further includes a third bank structure 400. The third bank structure 400 is located between the first insulating layer 130 and the second insulating layer 150, and arranged horizontally side by side with the semiconductor layer 140. The third bank structure 400 is also located between the semiconductor layer 140 and the channel 600, i.e., on the inner side of the channel 600. The third bank structure 400 is made of an insulating material. The binding strength between the third bank structure 400 and the first insulating layer 130 is greater than that between the third bank structure 400 and the second insulating layer 150.

In this implementation, a third bank structure 400 is disposed between the first insulating layer 130 and the second insulating layer 150. Due to the presence of the third bank structure 400 and the relatively high binding strength between the third bank structure 400 and the first insulating layer 130, harmful substances invading from the bonding interface between the first insulating layer 130 and the second insulating layer 150 toward the semiconductor layer 140 can only invade along the two sides and the top of the third bank structure 400, and cannot invade from the bonding interface between the third bank structure 400 and the first insulating layer 130, thereby extending the invasion path of the harmful substances. This implementation, combining the designs of the third bank structure 400 and the channel 600, significantly slows down or even blocks the invasion of harmful substances such as moisture or free ions, preventing them from penetrating into the active layer in the thin film transistor 100.

In some implementations, the third bank structure 400 may also be disposed on the outer side of the channel 600.

It should be noted that this implementation is based on the implementation corresponding to FIG. 4, with a further addition of the third bank structure 400, so that the semiconductor layer 140, the source electrode, and the drain electrode of the thin film transistor 100 are each provided with multiple protection structures.

Of course, in some implementations, the display substrate 20 may be provided only with the third bank structure 400, without the first bank structure 200 and the second bank structure 300. Alternatively, the display substrate 20 may be provided only with the third bank structure 400 and the first bank structure 200. Alternatively, the display substrate 20 may be provided only with the third bank structure 400 and the second bank structure 300.

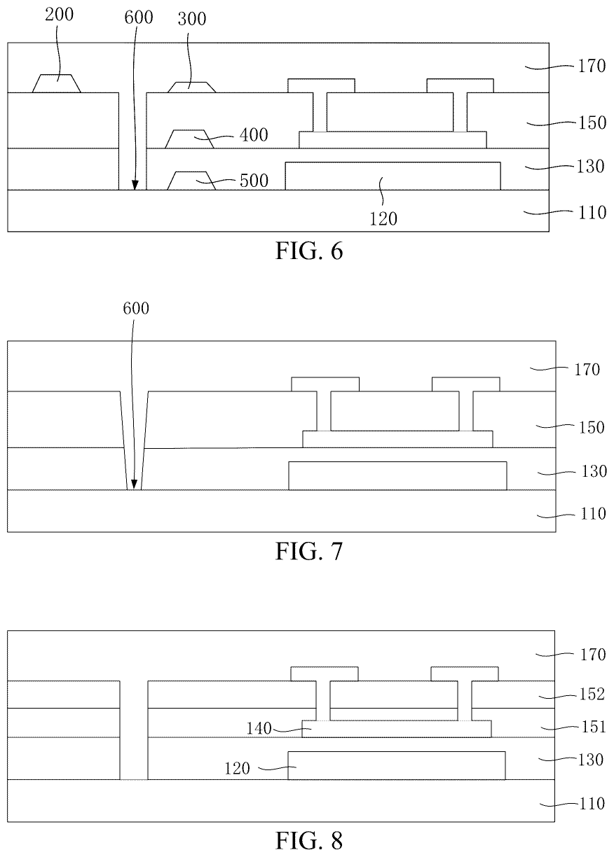

As another implementation, as shown in FIG. 6, the display substrate 20 further includes a gate electrode 120. The display substrate 20 is a bottom gate structure, in which the gate electrode 120 is disposed between the base 110 and the first insulating layer 130. The display substrate 20 further includes a fourth bank structure 500. The fourth bank structure 500 is disposed between the base 110 and the first insulating layer 130, and is arranged side by side with the gate electrode 120 in the horizontal direction. Furthermore, the fourth bank structure 500 is further located between the gate electrode 120 and the channel 600, on the inner side of the channel 600. The binding strength between the fourth bank structure 500 and the base 110 is greater than the binding strength between the fourth bank structure 500 and the first insulating layer 130.

In this implementation, a fourth bank structure 500 is disposed between the base 110 and the first insulating layer 130. Due to the presence of the fourth bank structure 500 and the relatively high binding strength between the fourth bank structure 500 and the base 110, harmful substances invading from the bonding interface between the base 110 and the first insulating layer 130 toward the gate electrode 120 can only infiltrate along the sides and top of the fourth bank structure 500, and cannot invade through the bonding interface between the fourth bank structure 500 and the base 110. As a result, the intrusion path of the harmful substances is extended. This implementation, by combining the designs of the fourth bank structure 500 and the channel 600, significantly slows down or even blocks the intrusion of harmful substances such as moisture or free ions into the gate electrode 120 of the thin film transistor 100.

In this implementation, the base 110 is made of glass, and the fourth bank structure 500 is integrally formed with the base 110.

In some implementations, the fourth bank structure 500 may also be disposed on the outer side of the channel 600.

As shown in FIG. 7, in some embodiments, in the thickness direction of the base 110, the cross-section of the channel 600 is an inverted trapezoid. Compared to the design where the channel 600 has a rectangular shape, the inverted trapezoid shape, with its sloped sides, results in a longer intrusion path for external harmful substances such as moisture or free ions as they infiltrate into the interior of the thin film transistor 100 along the sloped sides of the inverted trapezoid. Specifically, the bottom width of the channel 600 is 0.5-1 μm, the top width of the channel 600 is 1-2 μm, and the height of the channel 600 is 0.5-1.5 μm.

As shown in FIG. 8, in some embodiments, the second insulating layer 150 includes a first insulating dielectric layer 151 and a second insulating dielectric layer 152. The first insulating dielectric layer 151 is disposed on the side of the semiconductor layer 140 facing away from the first insulating layer 130. The second insulating dielectric layer 152 is disposed on the side of the first insulating dielectric layer 151 facing away from the semiconductor layer 140. The first insulating dielectric layer 151 is formed by chemical vapor deposition, followed by annealing, wherein the annealing temperature is 300-450° C. and the annealing time is 45-75 minutes. This design promotes the movement and coupling of ions and defects within the first insulating dielectric layer 151, thereby facilitating the volatilization of excess elements and reducing surface defects.

In some embodiments, the display substrate 20 includes a plurality of channels 600, each of which has an annular shape. The plurality of channels 600 are disposed in the display area of the display substrate 20 and disposed in one-to-one correspondence with the thin film transistors 100. Each channel 600 surrounds the corresponding thin film transistor 100, thereby blocking moisture or free ions and other harmful substances from all directions. Meanwhile, the first bank structure 200, the second bank structure 300, the third bank structure 400, and the fourth bank structure 500 may also be annular structures surrounding the corresponding thin film transistor 100, so as to enhance the blocking effect against moisture or free ions and other harmful substances for each thin film transistor.

In some embodiments, the channel 600 is disposed on each of both sides of the display substrate 20 and they are located on both sides in a lengthwise direction of the metal layer 160, thus preventing external moisture or free ions and other harmful substances from invading inward from the ends of the metal layer 160. Meanwhile, the first bank structure 200, the second bank structure 300, the third bank structure 400, and the fourth bank structure 500 can also be arranged only along the extending direction of the metal layer 160.

In some embodiments, the channel 600 is located in the non-display area of the display substrate 20, and there may be a single channel 600 or multiple channels 600, arranged to each surround the display area of the entire display substrate 20. Meanwhile, the first bank structure 200, the second bank structure 300, the third bank structure 400, and the fourth bank structure 500 may also be arranged to surround the display area of the display panel 10.

In some embodiments, the channel 600 is located in the non-display area of the display substrate 20, surrounding the entire GOA circuit. Meanwhile, the first bank structure 200, the second bank structure 300, the third bank structure 400, and the fourth bank structure 500 are also arranged to surround the GOA circuit of the display substrate 20.

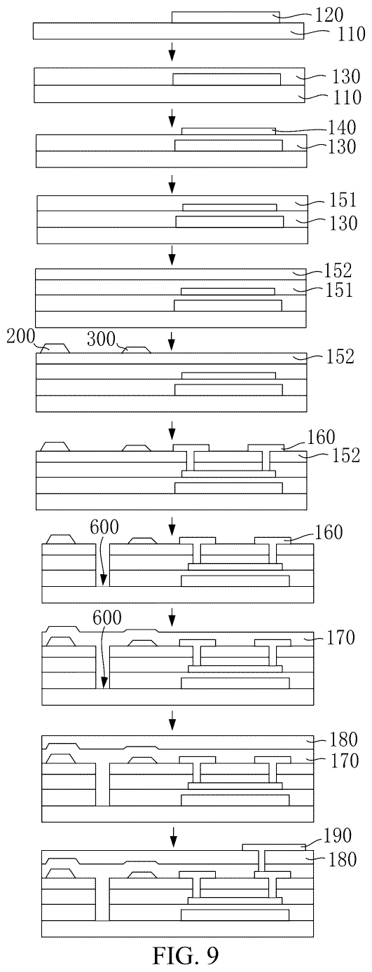

As shown in FIG. 9, an embodiment of the present application further provides a specific manufacturing process for the aforementioned display substrate 20. Taking the display substrate 20 as a bottom gate structure and the display substrate 20 having only the first bank structure 200 and the second bank structure 300 as an example, the specific steps are as follows.

A magnetron sputtering method is used to deposit the bottom gate electrode layer on a glass substrate. The bottom gate electrode layer may be formed as a single layer, double layer, multilayer metal alloy, pure metal, or conductive oxide, including but not limited to materials such as Cu, Mo, Al, Ti, Nb, Mg, Co, W, and In. Then, the bottom gate electrode layer is patterned by coating, exposure, development, etching (dry or wet etching), and stripping to obtain the gate electrode 120.

After the gate electrode 120 is formed, the first insulating layer 130 is formed on the surface of the gate electrode 120 by chemical vapor deposition or atomic layer deposition. The first insulating layer 130 includes, but is not limited to, one or a combination of multiple film layers of silicon oxide, silicon nitride, nitrogen silicon oxide, and aluminum oxide. In the embodiments of the present application, the first insulating layer 130 is at least a composite layer composed of two or more of the above-mentioned film layers. Furthermore, the film layer of the first insulating layer 130 adjacent to the gate electrode 120 is one of silicon nitride or nitrogen silicon oxide, and the film layer far from the gate electrode 120 is one of aluminum oxide or silicon oxide.

After the first insulating layer 130 is formed, an amorphous metal oxide semiconductor layer 140 is deposited on the surface of the first insulating layer 130 by magnetron sputtering. In this embodiment, the metal-oxide semiconductor material uses a metal oxide material with certain semiconductor characteristics (the elements contained in the material include but are not limited to In, Ga, Zn, O, and rare earth elements, and the content of In in the material differs from the content of other single metal elements) to achieve device characteristics with higher mobility. Then an annealing procedure is performed, where the annealing temperature is 260-450° C., and the annealing time is 45-90 minutes. A patterned metal-oxide semiconductor is therefore formed through coating, exposure, development, wet etching, and stripping, thereby obtaining the semiconductor layer 140.

After the semiconductor layer 140 is formed, the first insulating dielectric layer 151 is deposited by chemical vapor deposition. The first insulating dielectric layer 151 includes one or more films of materials such as silicon oxide, aluminum oxide, or silicon nitride, but is not limited thereto. The layer adjacent to the semiconductor layer 140 is one of a dense silicon oxide or aluminum oxide film, followed by annealing treatment, where the annealing temperature is 300-450° C. and the annealing time is 45-75 minutes.

After the first insulating dielectric layer 151 is formed, the second insulating dielectric layer 152 is formed by chemical vapor deposition or atomic layer deposition. The second insulating dielectric layer 152 includes one or more layers selected from silicon oxide, silicon nitride, nitrogen-doped silicon oxide, and aluminum oxide, but is not limited thereto. The second insulating dielectric layer 152 is at least a composite film consisting of two or more of the above layers, and the layer of the second insulating dielectric layer 152 adjacent to the first insulating dielectric layer 151 is one of the silicon oxide layer or aluminum oxide layer.

After the second insulating dielectric layer 152 is formed, an insulating layer is formed by chemical vapor deposition or atomic layer deposition. The insulating layer includes one or more layers selected from silicon oxide, silicon nitride, nitrogen-doped silicon oxide, and aluminum oxide, but is not limited thereto. That is, the insulating layer may be a single layer of the above-mentioned films or a composite film composed of two or more of these layers. Then, patterns are formed by coating, developing, etching, and stripping, thereby forming the first bank structure 200 and the second bank structure 300.

Then, by coating, developing, etching, and stripping, holes are formed above the semiconductor layer 140, penetrating to the surface of the semiconductor layer 140. Subsequently, ion implantation is performed on the exposed semiconductor layer 140 using an ion implantation device, where the processing gases used include but are not limited to BF3, Ar, He, and other gases.

Then, the metal layer 160 is deposited by magnetron sputtering. The metal layer 160 may be a single-layer, double-layer, or multi-layer structure composed of elemental metals, alloys, or conductive oxides (elemental metals and alloy elements include but are not limited to Cu, Mo, Al, Ti, Nb, Mg, Co, W, In, and O). If it is a double-layer or multi-layer structure, the bottom metal in the metal layer 160 is consistent with the metal of the gate electrode 120 to reduce the potential difference caused by material differences. Then, photoresist coating, development, etching, and stripping are performed to pattern the source and drain electrodes.

Then, holes are etched down to the base 110 to form a patterned channel 600 structure, which extends the travel path of moisture and free ions. The number of channel 600 structures is not limited and can be one or multiple distributed channels. The channel 600 may be of an inverted trapezoid structure with a bottom width of 0.5-1 μm, a top width of 1-2 μm, and a height of 0.5-1.5 μm, or of a stacked double-trapezoid structure.

Then, the third insulating layer 170 is deposited by chemical vapor deposition. The third insulating layer 170 includes but is not limited to a film of silicon oxide, silicon nitride, oxynitride silicon oxide, or aluminum oxide, and may be a composite layer composed of two or more of the above film layers.

Subsequently, as needed, an organic insulating layer 180 may be formed on the third insulating layer 170 for planarization, followed by coating, developing, and etching to form the patterned holes in the organic insulating layer 180 and the third insulating layer 170.

Finally, a pixel defining layer 190 is formed by magnetron sputtering. The material of this layer may be a single layer, double layer, or multilayer of elemental metal, alloy, or oxide (the metal elements in elemental metal, alloy, or oxide include but are not limited to Cu, Mo, Al, Ti, Nb, Mg, Co, W, In, O, Zn, Ga). Then, coating, developing, etching, and stripping are performed for patterning, followed by annealing at a temperature of 200-280° C. for 25-45 minutes, thereby completing the fabrication of the display substrate 20.

Of course, the thin film transistor 100 may also use polycrystalline high-mobility oxide semiconductor material as the semiconductor layer 140, or use stacked metal semiconductor oxide materials with different mobilities as the semiconductor layer 140, so as to ensure device stability while maintaining the high mobility of the thin film transistor 100 device.

It should be noted that the limitations of the various steps involved in this solution are not to be interpreted to limit the order of the steps, under the premise of not affecting the implementation of the specific solution. The steps written earlier can be executed first, or later, or even at the same time as the steps written later. The solutions of different embodiments may be combined and applied, provided that there is no conflict between them. As long as this solution can be implemented, it should be regarded as falling within the scope of protection of this application.

The foregoing is a further detailed description of the present application with reference to some specific optional implementations, but it cannot be determined that the specific implementation of the present application is limited to these implementations. For those having ordinary skill in the technical field to which the present application pertains, several deductions or substitutions may be made without departing from the concept of the present application, and all these deductions or substitutions should be regarded as falling in the scope of protection of the present application.

What is claimed is:

1. A display substrate, comprising:
a base;
a first insulating layer, disposed on the base;
a semiconductor layer, disposed on a side of the first insulating layer facing away from the base;
a second insulating layer, disposed on a side of the semiconductor layer facing away from the first insulating layer;
a metal layer, disposed on a side of the second insulating layer facing away from the semiconductor layer; and
a third insulating layer, disposed on the metal layer;
wherein the semiconductor layer and the metal layer constitute part of each of a plurality of thin film transistors in the display substrate, wherein the display substrate further comprises at least one channel, the at least one channel being disposed on at least one side of each thin film transistor and penetrating through the first insulating layer and the second insulating layer, and wherein the third insulating layer further fills the at least one channel and is bonded to the base within the at least one channel.

2. The display substrate as recited in claim 1, further comprising a first bank structure disposed between the second insulating layer and the third insulating layer and adjacent to the at least one channel;
wherein the first bank structure is made of an insulating material, and wherein a binding strength between the first bank structure and the second insulating layer is greater than a binding strength between the first bank structure and the third insulating layer.

3. The display substrate as recited in claim 2, further comprising a second bank structure disposed between the second insulating layer and the third insulating layer, wherein the at least one channel is located between the first bank structure and the second bank structure;
wherein a binding strength between the second bank structure and the second insulating layer is greater than a binding strength between the second bank structure and the third insulating layer.

4. The display substrate as recited in claim 3, wherein the first bank structure and the second bank structure are formed through the same manufacturing procedure.

5. The display substrate as recited in claim 2, wherein an area in which the first bank structure contacts the second insulating layer is greater than an area in which the first bank structure contacts the third insulating layer.

6. The display substrate as recited in claim 5, wherein in a thickness direction of the base, a cross-section of the first bank structure is a trapezoid, wherein a width of a side of the first bank structure contacting the second insulating layer lies in a range of 2.8 μm to 3.2 μm, wherein a width of a side of the first bank structure contacting the third insulating layer lies in a range of 1.5 μm to 2.5 μm, and wherein a height of the first bank structure lies in a range of 0.5 μm to 0.8 μm.

7. The display substrate as recited in claim 2, wherein a material of the first bank structure is identical with a material of the second insulating layer, and different from a material of the third insulating layer.

8. The display substrate as recited in claim 2, wherein a film formation rate of the first bank structure is higher than a film formation rate of the third insulating layer.

9. The display substrate as recited in claim 3, further comprising a third bank structure disposed between the first insulating layer and the second insulating layer and arranged horizontally side by side with the semiconductor layer, and wherein the third bank structure is further disposed between the semiconductor layer and the at least one channel;
wherein the third bank structure is made of an insulating material, and wherein a binding strength between the third bank structure and the first insulating layer is greater than a binding strength between the third bank structure and the second insulating layer.

10. The display substrate as recited in claim 9, further comprising a gate electrode disposed between the base and the first insulating layer;
wherein the display substrate further comprises a fourth bank structure disposed between the base and the first insulating layer and arranged horizontally side by side with the gate electrode, and wherein the fourth bank structure is further disposed between the gate electrode and the at least one channel;
wherein a binding strength between the fourth bank structure and the base is greater than a binding strength between the fourth bank structure and the first insulating layer.

11. The display substrate as recited in claim 10, wherein the fourth bank structure and the base are integrally formed.

12. The display substrate as recited in claim 1, wherein in a thickness direction of the base, a cross-section of the at least one channel is an inverted trapezoid.

13. The display substrate as recited in claim 12, wherein a bottom width of the at least one channel lies in a range of 0.5 μm to 1 μm, a top width of the at least one channel lies in a range of 1 μm to 2 μm, and a height of the at least one channel lies in a range of 0.5 μm to 1.5 μm.

14. The display substrate as recited in claim 1, wherein the second insulating layer comprises a first insulating dielectric layer and a second insulating dielectric layer, the first insulating dielectric layer being disposed on a side of the semiconductor layer facing away from the first insulating layer, and the second insulating dielectric layer being disposed on a side of the first insulating dielectric layer facing away from the semiconductor layer;
wherein the first insulating dielectric layer is formed by chemical vapor deposition followed by an annealing process, wherein ions and defects inside the first insulating dielectric layer migrate and couple thus promoting volatilization of excess elements and reducing surface defects.

15. The display substrate as recited in claim 14, wherein an annealing temperature lies in a range of 300 to 450° C., and an annealing time lies in a range of 45 to 75 minutes.

16. The display substrate as recited in claim 1, wherein the at least one channel comprises a plurality of channels, which are disposed in a display area of the display substrate and disposed in one-to-one correspondence with the plurality of thin film transistors, wherein each of the plurality of channels has an annular shape and surrounds a respective thin film transistor.

17. The display substrate as recited in claim 1, wherein the at least one channel is disposed in a non-display area of the display substrate, wherein each of the at least one channel has an annular shape and is arranged to surround a display area of the display substrate.

18. The display substrate as recited in claim 1, wherein the at least one channel is disposed on both sides of the display substrate, and disposed on both sides in a length direction of the metal layer.

19. A display substrate, comprising:
a base;
a first insulating layer, disposed on the base;
a semiconductor layer, disposed on a side of the first insulating layer facing away from the base;
a second insulating layer, disposed on a side of the semiconductor layer facing away from the first insulating layer;
a metal layer, disposed on a side of the second insulating layer facing away from the semiconductor layer;
a third insulating layer, disposed on the metal layer;
a first bank structure, disposed between the second insulating layer and the third insulating layer and made of an insulating material, wherein a binding strength between the first bank structure and the second insulating layer is greater than a binding strength between the first bank structure and the third insulating layer; and
a second bank structure, disposed between the second insulating layer and the third insulating layer, formed by the same manufacturing procedure as the first bank structure, wherein a binding strength between the second bank structure and the second insulating layer is greater than a binding strength between the second bank structure and the third insulating layer;
wherein the semiconductor layer and the metal layer constitute part of each of a plurality of thin film transistors in the display substrate, wherein the display substrate further comprises at least one channel disposed on at least one side of each thin film transistor, the at least one channel penetrating through the first insulating layer and the second insulating layer, wherein the third insulating layer fills the at least one channel and is bonded to the base within the at least one channel;
wherein the at least one channel is disposed between the first bank structure and the second bank structure.

20. A display panel, comprising a display substrate, the display substrate comprising:
a base;
a first insulating layer, disposed on the base;
a semiconductor layer, disposed on a side of the first insulating layer facing away from the base;
a second insulating layer, disposed on a side of the semiconductor layer facing away from the first insulating layer;
a metal layer, disposed on a side of the second insulating layer facing away from the semiconductor layer; and
a third insulating layer, disposed on the metal layer;
wherein the semiconductor layer and the metal layer constitute part of each of a plurality of thin film transistors in the display substrate, wherein the display substrate further comprises at least one channel, the at least one channel being disposed on at least one side of each thin film transistor and penetrating through the first insulating layer and the second insulating layer, and wherein the third insulating layer further fills the at least one channel and is bonded to the base within the at least one channel.
